(19) United States
(12) Patent Application Publication
(10) Pub. No.: US 2024/0234072 A9
(43) Pub. Date: Jul. 11, 2024

(54) A UV SENSITIVE PHOTOCATHODE, A METHOD FOR PRODUCING A UV SENSITIVE PHOTOCATHODE, AND A DETECTOR FOR MEASURING UV RADIATION

(71) Applicant: FENNO-AURUM OY, Espoo (FI)

(72) Inventor: Heikki Johannes Sipilä, Espoo (FI)

(73) Assignee: FENNO-AURUM OY, Espoo (FI)

(21) Appl. No.: 18/547,317

(22) PCT Filed: Feb. 22, 2021
(86) PCT No.: PCT/FI2021/050129

§ 371 Date: Aug. 21, 2023

(51) Int. Cl. H01J 9/12; C23C 14/06; H01J 1/34

(52) U.S. Cl. CPC H01J 9/12; C23C 14/0605; H01J 1/34; H01J 2201/30476; H01J 2209/012

(57) ABSTRACT

An ultraviolet (UV) sensitive photocathode includes a support structure, and an amorphous diamond-like carbon coating on the support structure. A method produces the UV sensitive photocathode. A UV sensitive detector is for measuring UV radiation and includes the UV sensitive photocathode.

### TECHNICAL FIELD

The invention concerns in general the technical field of UV sensitive photocathodes. Especially the invention concerns UV sensitive photocathodes of detectors for measuring UV radiation.

### BACKGROUND

Ultraviolet (UV) sensitive photocathodes may typically be used for example in UV sensitive detectors. The UV sensitive detectors may be used for example to detect flames or sparks, which emit UV radiation at a wavelength band between 185 and 280 nanometers. A typical material for the photocathode may be cesium iodide (CsI), which is sensitive to UV radiation. However, CsI is highly hygroscopic material and thus the handling of CsI is difficult. Moreover, CsI has poor stability because of its highly hygroscopic nature.

Another substantially promising material for the UV sensitive photocathodes is diamond. Diamond is of great interest because of its very low electronic affinity, its chemical stability, its resistance to UV radiation and because of its heat dissipation properties. Typically, chemical vapour deposition (CVD) methods are used to the diamond films. The CVD methods use some hydrocarbon gas, such as methane, as a precursor and the deposited coatings are typically polycrystalline. Therefore, the diamond films deposited with CVD method are full of grain boundaries and contain significant amounts of hydrogen. The processing temperature in the CVD method is very high, i.e. above 600° C., which limits the choice of substrate materials. Moreover, CVD diamond film has typically high resistivity and low quantum efficiency.

Thus, there is a need for developing solutions to produce UV sensitive photocathodes.

### SUMMARY

The following presents a simplified summary in order to provide basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

An objective of the invention is to present a UV sensitive photocathode, a method for producing a UV sensitive photocathode, and a detector for measuring UV radiation. Another objective of the invention is that the UV sensitive photocathode, the method for producing a UV sensitive photocathode, and the detector for measuring UV radiation enable providing a solar blind and UV sensitive photocathode for UV sensitive detector applications.

The objectives of the invention are reached by a UV sensitive photocathode, a method for producing a UV sensitive photocathode, and a detector for measuring UV radiation as defined by the respective independent claims.

According to a first aspect, a UV sensitive photocathode is provided, wherein the UV sensitive photocathode comprises: a support structure, and an amorphous diamond-like carbon coating on the support structure.

The amorphous diamond-like carbon coating may be produced with a pulsed arc-discharge deposition process.

Alternatively or in addition to the above-described, the amorphous diamond-like carbon coating may be doped with nitrogen, hydrogen, or deuterium.

Alternatively or in addition to the above-described, a thickness of the amorphous diamond-like carbon coating may be between 100 to 300 nanometers.

Alternatively or in addition to the above-described, the support structure may be made of metal or silicon.

Alternatively or in addition to the above-described, the support structure may be an inner surface of a detector comprising the UV sensitive photocathode or a separate support structure which is mountable to a detector comprising the UV sensitive photocathode.

According to a second aspect, a method for producing a UV sensitive photocathode is provided, wherein the method comprises: preparing a support structure, and producing an amorphous diamond-like carbon coating on the support structure.

The amorphous diamond-like carbon coating may be produced with a pulsed arc-discharge deposition process.

The pulsed arc-discharge deposition process may comprise: producing a pulsed carbon plasma by a vacuum arc-discharge by using a high voltage discharge arc, and conveying the produced carbon plasma to the support structure to produce the amorphous coating on the support structure.

Alternatively or in addition to the above-described, the method may further comprise doping the amorphous diamond-like carbon coating with nitrogen, hydrogen, or deuterium.

Alternatively or in addition to the above-described, the support structure may be at a temperature between 20 to 250° C. during the producing of the amorphous diamond-like carbon coating.

Alternatively or in addition to the above-described, the preparing the support structure may comprise polishing the support structure.

Alternatively or in addition to the above-described, a thickness of the amorphous diamond-like carbon coating may be between 100 to 300 nanometers.

Alternatively or in addition to the above-described, the support structure may be made of metal or silicon.

According to a third aspect, a UV sensitive detector for measuring UV radiation is provided, wherein the UV sensitive detector comprises the UV sensitive photocathode as described above.

Various exemplifying and non-limiting embodiments of the invention both as to constructions and to methods of operation, together with additional objects and advantages thereof, will be best understood from the following description of specific exemplifying and non-limiting embodiments when read in connection with the accompanying drawings.

The verbs “to comprise” and “to include” are used in this document as open limitations that neither exclude nor require the existence of unrecited features.

The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF FIGURES

The embodiments of the invention are illustrated by way of example, and not by way of limitation, in the figures of the accompanying drawings.

FIG. 1 illustrates schematically an example of a UV sensitive photocathode according to the invention.

FIG. 2 illustrates schematically an example of a method according to the invention.

FIG. 3 illustrates schematically another example of a method according to the invention.

### DESCRIPTION OF THE EXEMPLIFYING EMBODIMENTS

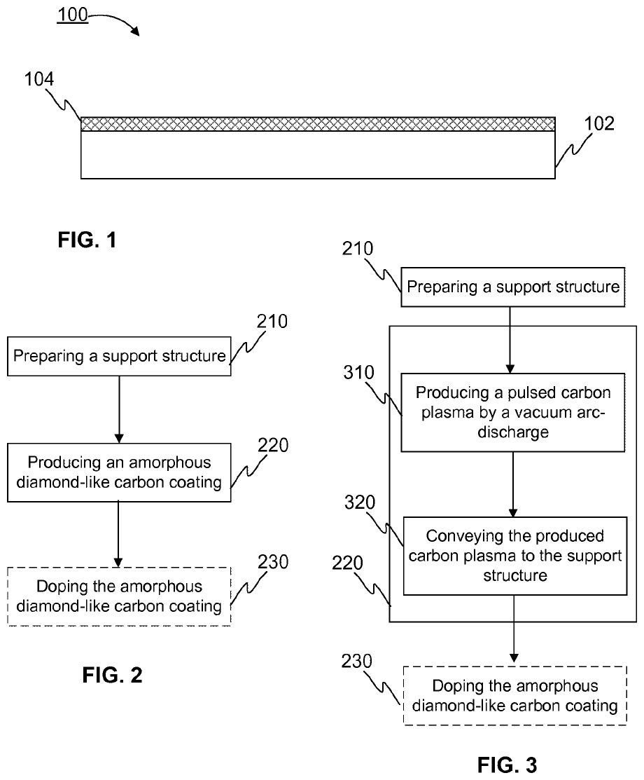

FIG. 1 illustrates schematically an example of an ultraviolet (UV) sensitive photocathode 100 according to the invention. The UV sensitive photocathode 100 comprises a support structure 102 and an amorphous diamond-like carbon coating 104 produced on the support structure 102. The UV sensitive photocathode 100 according to the invention may be used for example in a UV sensitive detector configured to measure UV radiation. A non-limiting example of the UV sensitive detector to which the UV sensitive photocathode 100 according to the invention may be implemented in may be a UV flame detector. However, the structure of the UV sensitive detector is not limited and the UV sensitive photocathode 100 according to the invention may be implemented in any kind of UV sensitive detector. In the example of FIG. 1 the UV sensitive photocathode 100 has a planar shape, but the invention is not limited to that, and the UV sensitive photocathode 100 may have also other shapes, e.g. convexly curved or concavely curved.

As already the name of the coating 104 refers, the structure of the amorphous diamond-like carbon coating 104 is amorphous. The amorphous diamond-like carbon coating 104 does not have any crystalline structure. For example, diamond and graphite have crystalline structure. The structure of the amorphous diamond-like carbon coating is very stable. The amorphous diamond-like carbon coating does not have a hygroscopic nature, as for example cesium iodide (CO coatings have. The amorphous diamond-like carbon coating 104 is solar blind and sensitive to UV radiation, i.e. is UV sensitive. This enables that the photocathode 100 comprising the amorphous diamond-like carbon coating 104 is also solar blind and sensitive to UV radiation, i.e. is UV sensitive. Moreover, the amorphous diamond-like carbon coating 104 and the photocathode 100 comprising the amorphous diamond-like carbon coating 104 are insensitive to a radiation at longer wavelengths, which dominates the daylight. Daylight is a combination of all direct and indirect sunlight during the daytime.

The amorphous diamond-like carbon coating 104 may be produced, i.e. manufactured, with a physical vapor deposition (PVD) process. More specifically, the amorphous diamond-like carbon coating 104 according to the invention may be produced with a pulsed arc-discharge deposition process, which is a PVD process. A thickness of the produced amorphous diamond-like carbon coating 104 may be between 100 to 300 nanometers. The manufacturing process of the UV sensitive photocathode 100 according to the invention and especially, the deposition process of the amorphous diamond-like carbon coating 104 of the UV sensitive photocathode 100 enables an improved mechanical strength, i.e. mechanical hardness, of the amorphous diamond-like carbon coating 104. In other words, the amorphous diamond-like carbon coating 104 produced with the pulsed arc-discharge deposition process is extremely strong, for example in comparison to the CsI coating and a diamond coating. Alternatively or in addition, the amorphous diamond-like carbon coating 104 of the UV sensitive photocathode 100 according to the invention has an improved quantum efficiency, for example in comparison to the CVD diamond film coating. Moreover, the amorphous diamond-like carbon coating 104 according to the invention is chemically inert, i.e. is not chemically reactive. In other words, the amorphous diamond-like carbon coating 104 according to the invention does not react chemically with other substances. The method for producing, i.e. manufacturing, the UV sensitive photocathode 100 according to the invention will be discussed more later in this application referring to FIGS. 2 and 3.

The amorphous diamond-like carbon coating 104 may be doped with nitrogen, hydrogen, or deuterium. The nitrogen content of the doped amorphous diamond-like carbon coating 104 may be e.g. between 0.2 to 2%. Alternatively or in addition, the hydrogen content of the doped amorphous diamond-like carbon coating 104 may be e.g. between 0.1 to 1%. Alternatively or in addition, the deuterium content of the doped amorphous diamond-like carbon coating 104 may be e.g. between 0.1 to 1%. The doping of the amorphous diamond-like carbon coating 104 improves the stability of the amorphous diamond-like carbon coating 104. Because the amorphous diamond-like carbon itself is has a low conductivity, the doping increases the conductivity of the amorphous diamond-like carbon coating 104, which enables a stable operation of the amorphous diamond-like carbon coating 104. The doping process is well a controlled industrial operation. Doping with the hydrogen or the deuterium may be used to increase a quantum efficiency of the photocathode 100. Doping with the nitrogen increases a conductivity of the photocathode 100.

The support structure 102 may be at a temperature between 20 to 250° C. during the producing of the amorphous diamond-like carbon coating 104. This enables that the UV sensitive photocathode 100 may be produced even at a room temperature. The room temperature may typically comprise temperatures between about 20 to 22° C.

The support structure, e.g. a substrate, 102 may preferably be made of a conductive material. This enables that the support structure 102 may be kept at a desired potential in comparison with an anode of the UV sensitive detector, when the photocathode 100 is implemented in the UV sensitive detector. For example, the support structure 102 may be made of metal, e.g. stainless steel; or silicon. The support structure 102 may be an inner surface of the UV sensitive detector, which comprises the UV sensitive photocathode 100 or of which the UV sensitive photocathode 100 is a part. In other words, the amorphous diamond-like carbon coating 104 of the UV sensitive photocathode 100 may be deposited directly on the inner surface of the UV sensitive detector to establish, i.e. constitute, the UV sensitive photocathode 100 of the UV sensitive detector. Alternatively, the support structure 102 may be a separate support structure, e.g. a separate substrate, which is mountable to the UV sensitive detector. In other words, the UV sensitive photocathode 100 may be manufactured by producing the amorphous diamond-like carbon coating 104 on a separate support structure 102. The produced UV sensitive photocathode 100, i.e. the structure comprising the support structure 102 and the amorphous diamond-like carbon coating 104, may then be mounted to the UV sensitive detector. The UV sensitive photocathode 100 may be mounted to the detector so that the support structure 102 is facing towards an inner surface of the UV sensitive detector.

The support structure 102 may be polished before the amorphous diamond-like carbon coating 104 is produced on the support structure 102. The polishing of the support structure 102 reduces sharp edges and/or rims on a surface of the support structure 102 to which the amorphous diamond-like carbon coating 104 is produced. The sharp edges and/or rims may increase stress and/or result in a delamination of the amorphous diamond-like carbon coating 104. The polishing of the support structure 102 also reduces the roughness of the surface of the support structure 102 to which the amorphous diamond-like carbon coating 104 is produced. Alternatively or in addition, one or more other preparatory operations of the support structure 102, on which the amorphous diamond-like carbon coating 104 will be produced, may be performed before the amorphous diamond-like carbon coating 104 is produced on the support structure 102.

Above the invention is described by referring to the UV sensitive photocathode 100 according to the invention. The invention relates also to a method for producing, i.e. manufacturing, the UV sensitive photocathode 100. Next the invention is defined referring to FIG. 2 schematically illustrating an example of a method according to the invention. FIG. 2 schematically illustrates the invention as a flow chart.

At a step, 210 the support structure 102 is prepared. The preparing of the support structure 102 may comprise for example polishing the support structure 102. The polishing of the support structure 102 reduces sharp edges and/or rims on a surface of the support structure 102 to which the amorphous diamond-like carbon coating 104 is produced. The sharp edges and/or rims may increase stress and/or result in a delamination of the amorphous diamond-like carbon coating 104. The polishing of the support structure 102 also reduces the roughness of the surface of the support structure 102 to which the amorphous diamond-like carbon coating 104 is produced. The preparing of the support structure 102 at the step 210 may alternatively or in addition comprise one or more other preparatory operations of the support structure 102 on which the amorphous diamond-like carbon coating 104 will be produced.

At a step 220, the amorphous diamond-like carbon coating 104 is produced on the support structure 102, i.e. on top of the support structure 102. The amorphous diamond-like carbon coating 104 may be produced, i.e. manufactured, with a physical vapor deposition (PVD) process at the step 220.

More specifically, the amorphous diamond-like carbon coating 104 according to the invention may be produced with a pulsed arc-discharge deposition process, which is a PVD process. The pulsed arc-discharge deposition process is developed for coating surfaces of mechanical devices, e.g. tools and instruments, in order to reduce friction and wear of the surfaces. The pulsed arc-discharge deposition process has also been used for coating surfaces of mechanical devices in medical applications in order to reduce wear of the surfaces.

The method may further comprise doping the amorphous diamond-like carbon coating 104 with nitrogen, hydrogen, or deuterium at a step 230. The nitrogen content of the doped amorphous diamond-like carbon coating 104 may be e.g. between 0.2 to 2%. Alternatively or in addition, the hydrogen content of the doped amorphous diamond-like carbon coating 104 may be e.g. between 0.1 to 1%. Alternatively or in addition, the deuterium content of the doped amorphous diamond-like carbon coating 104 may be e.g. between 0.1 to 1%. The doping of the amorphous diamond-like carbon coating 104 improves the stability of the amorphous diamond-like carbon coating 104. Because the amorphous diamond-like carbon itself has a low conductivity, the doping increases the conductivity of the amorphous diamond-like carbon coating 104, which enables a stable operation of the amorphous diamond-like carbon coating 104. The doping process is well a controlled industrial operation. Doping with the hydrogen or the deuterium may be used to increase the quantum efficiency of the photocathode 100. Doping with the nitrogen increases a conductivity of the photocathode 100.

FIG. 3 schematically illustrates an example of the pulsed arc-discharge deposition process of the amorphous diamond-like carbon coating 104. In other words, FIG. 3 schematically illustrates the flow chart of FIG. 2 more in detail. Especially, the step 220, i.e. the producing of the amorphous diamond-like carbon coating 104 on the support structure 102, becomes clear from FIG. 3.

At a step 310 of the pulsed arc discharge process, a pulsed carbon plasma is produced by a vacuum arc-discharge by using a high voltage discharge arc For example, the pulsed carbon plasma may be produced by the arc-discharge between a cathode and an anode in a vacuum. The cathode may be e.g. a graphite cathode that enables producing dense carbon plasma. According to an example the pulsed carbon plasma may be produced, i.e. generated, with a pulse plasma generating system, e.g. a pulse plasma generator. The cathode and the anode may form a plasma accelerating stage of the pulse plasma generating system. At least a part of the cathode material may be vaporized and ionized by an ignition system, e.g. an ignition electrode, to ignite the plasma. In other words, the producing of the pulsed carbon plasma may comprise using the high voltage discharge arc to produce the pulsed carbon plasma. To be more precise, the high voltage discharge arc may be used between the ignition system and the cathode to produce an ignition plasma, which initiates the main arc-discharge to produce the pulsed carbon plasma, i.e. the ignition plasma initiates the arc-discharge between the cathode and the anode.

At a step 320 of the pulsed arc discharge process, the produced carbon plasma is conveyed, i.e. transported, to the support structure 102 to produce the amorphous diamond-like carbon coating 104 on the support structure 102. The generated carbon plasma may be in a form of a plume having a high velocity (e.g. in order of 10⁴ m/s) and being highly directional. The conveying of the produced carbon plasma to the support structure 102 may comprise first conveying the produced carbon plasma through an aperture of the anode. The conveying of the produced carbon plasma to the support structure may further comprise focusing and guiding the produced pulsed carbon plasma by a solenoid to the support structure 102. The solenoid may be arranged in series with the plasma accelerating stage formed by the cathode and the anode. The focusing effect of the solenoid results in a high concentration of the carbon plasma at the support structure. A thickness of the produced amorphous diamond-like carbon coating 104 of the photocathode 100 may be between 100 to 300 nanometers.

The support structure 102 may be at a temperature between 20 to 250° C. during the producing of the amorphous diamond-like carbon coating 104 at the step 220. This enables that the UV sensitive photocathode 100 may be produced even at a room temperature as discussed above.

The support structure, e.g. a substrate, 102 may preferably be made of a conductive material. This enables that the support structure 102 may be kept at a desired potential in comparison with an anode of the UV sensitive detector, when the photocathode 100 is implemented in the UV sensitive detector. For example, the support structure 102 may be made of metal, e.g. stainless steel; or silicon. The amorphous diamond-like carbon coating 104 of the UV sensitive photocathode 100 may be deposited directly on an inner surface of the UV sensitive detector to establish, i.e. constitute, the UV sensitive photocathode 100 of the UV sensitive detector at the step 220. In other words, the support structure 102 may be an inner surface of the UV sensitive detector, which comprises the UV sensitive photocathode 100 or of which the UV sensitive photocathode 100 is a part. Alternatively, the UV sensitive photocathode 100 may be manufactured by producing the amorphous diamond-like carbon coating 104 on a separate support structure, e.g. a separate substrate, 102 at the step 220. The produced UV sensitive photocathode 100, i.e. a structure comprising the support structure 102 and the amorphous diamond-like carbon coating 104, may then be mounted to the UV sensitive detector. The UV sensitive photocathode 100 may be mounted to the detector so that the support structure 102 is facing towards an inner surface of the UV sensitive detector. In other words, the support structure 102 may be a separate support structure, which is mountable to the UV sensitive detector.

The above-described manufacturing method of the UV sensitive photocathode 100 according to the invention and especially, the deposition process of the amorphous diamond-like carbon coating 104 of the UV sensitive photocathode 100 enables an improved mechanical strength, i.e. mechanical hardness, of the amorphous diamond-like carbon coating 104. In other words, the amorphous diamond-like carbon coating 104 produced with the pulsed arc-discharge deposition process is extremely strong, for example in comparison to the CsI coating and the diamond film coating. Alternatively or in addition, the amorphous diamond-like carbon coating 104 of the UV sensitive photocathode 100 according to the invention has an improved quantum efficiency, for example in comparison to the CVD diamond film coating. Moreover, the amorphous diamond-like carbon coating 104 of the UV sensitive photocathode 100 according to the invention is chemically inert, i.e. is not chemically reactive. In other words, the amorphous diamond-like carbon coating 104 does not react chemically with other substances. Alternatively or in addition, the above-described manufacturing method of the UV sensitive photocathode 100 according to the invention enables deposition of photocathodes having substantially large area. The photocathodes with the substantially large area may be used for example to improve UV sensitivity of a UV sensitive detector. These large area photocathodes may be used for example in scientific applications, such as measuring Cerenkov radiation.

The invention relates also to a UV sensitive detector for measuring UV radiation. The UV sensitive detector according to the invention comprises the UV sensitive photocathode 100 described above. The UV sensitive detector according to the invention may be used for example for detecting flames or sparks, which emit UV radiation at a wavelength band between 185 and 280 nanometers. The UV sensitive detector according to the invention may further comprise other components or parts, e.g. an anode, housing, etc. A non-limiting example of the UV sensitive detector according to the invention may be a UV flame detector. The solar blindness and UV sensitivity of the UV sensitive photocathode 100 according to the invention enables that the UV sensitive detector comprising the UV sensitive photocathode 100 according to the invention is solar blind and UV sensitive. It also enables that the UV sensitive detector comprising the UV sensitive photocathode 100 according to the invention is insensitive to the radiation at longer wavelengths, which dominates the daylight.

The specific examples provided in the description given above should not be construed as limiting the applicability and/or the interpretation of the appended claims. Lists and groups of examples provided in the description given above are not exhaustive unless otherwise explicitly stated.

1. An ultraviolet sensitive photocathode comprising:
a support structure, and
an amorphous diamond-like carbon coating on the support structure.

2. The UV sensitive photocathode according claim 1, wherein the amorphous diamond-like carbon coating comprises a pulsed arc-discharge deposited coating.

3. The UV sensitive photocathode according to claim 1, wherein the amorphous diamond-like carbon coating is doped with nitrogen, hydrogen, or deuterium.

4. The UV sensitive photocathode according to claim 1, wherein a thickness of the amorphous diamond-like carbon coating is between 100 to 300 nanometers.

5. The UV sensitive photocathode according to claim 1, wherein the support structure is made of metal or silicon.

6. The UV sensitive photocathode according to claim 1, wherein the support structure is an inner surface of a detector comprising the UV sensitive photocathode or a separate support structure which is mountable to a detector comprising the UV sensitive photocathode.

7. A method for producing an ultraviolet sensitive photocathode, the method comprising:
preparing a support structure, and
producing an amorphous diamond-like carbon coating on the support structure.

8. The method according to claim 7, wherein the amorphous diamond-like carbon coating is produced with a pulsed arc-discharge deposition process.

9. The method according to claim 8, wherein the pulsed arc-discharge deposition process comprises:
producing a pulsed carbon plasma by a vacuum arc-discharge using a high voltage discharge arc, and
conveying the produced carbon plasma to the support structure to produce the amorphous coating on the support structure.

10. The method according to claim 7, further comprising doping the amorphous diamond-like carbon coating with nitrogen, hydrogen, or deuterium.

11. The method according to claim 7, wherein the support structure is at a temperature between 20 to 250° C. during the producing of the amorphous diamond-like carbon coating.

12. The method according to claim 7, wherein the preparing the support structure comprises polishing the support structure.

13. The method according to claim 7, wherein a thickness of the amorphous diamond-like carbon coating is between 100 to 300 nanometers.

14. The method according to claim 7, wherein the support structure is made of metal or silicon.

15. A UV sensitive detector for measuring UV radiation, wherein the detector comprises the UV sensitive photocathode according to claim 1.
